(19) United States
(12) Patent Application Publication
(10) Pub. No.: US 2022/0240494 A1
(43) Pub. Date: Aug. 4, 2022

(54) AERIAL SENSOR AND MANIPULATION PLATFORM FOR FARMING AND METHOD OF USING SAME

(71) Applicant: Neatleaf, Inc., Scotts Valley, CA (US)

(72) Inventors: Ralf Schonherr, San Francisco, CA (US); Elmar Mair, Santa Cruz, CA (US)

(21) Appl. No.: 17/586,118

(22) Filed: Jan. 27, 2022

Related U.S. Application Data
(60) Provisional application No. 63/143,684, filed on Jan. 29, 2021.

(51) Int. Cl. A01M 7/00; G01R 19/00; G01D 21/02; G01S 17/08; B25J 19/02; A01G 13/10

(52) U.S. Cl. CPC A01M 7/0089; G01R 19/0092; A01G 13/10; G01S 17/08; B25J 19/021; G01D 21/02

(57) ABSTRACT

A robotic sensor and manipulation platform for farming is disclosed, having a robotic base and one or more exchangeable robotic sensing and manipulation tips deployable from the robotic base to commanded positions in a plant growth area. The robotic sensing and manipulation tips having a plurality of sensors adapted to detect and monitor plant health and growth conditions, and a computer-based control system configured analyze sensor data and provide analyzed results to the farmer or producer.

### CROSS-REFERENCE TO RELATED APPLICATION

This application claims the benefit of U.S. Provisional Application No. 63/143,684, filed Jan. 29, 2021. The entire contents of the aforesaid U.S. Provisional Application being incorporated herein by reference and to the fullest extent permitted by the law.

### TECHNICAL FIELD

This disclosure generally relates to robotic farming, particularly to autonomous computer controlled robotic aerial sensor and manipulation platforms having deployable sensing and manipulation tips, specifically for farming or alternately indoor greenhouse environments. The disclosure includes cable robots that include a cable positioned robotic device suspended from a set of cables and respective support structures and more particular robots in the field of agriculture, with one or preferably a plurality of interchangeable sensing and or manipulating devices.

### BACKGROUND OF THE INVENTION

There are various reasons to tend plants on an individual level or at least on a level of only a few plants. For example, the use of fertilizer or pesticides may be reduced to the minimum necessary level for each plant; expensive or delicate plants may be grown more successfully; for toxic plants it might be necessary to track growth on an individual level to fulfil legal requirements; and in scientific environments results for studies may be obtained faster by individual tracking and adjusting growth parameters for each plant. Vertical farming, with highly packed plants on several levels in buildings in metropolitan urban areas may benefit from a close monitoring for individual or groups of few plants.

Tracking of the growth of plants may be done manually. However, in a commercial style environment for many plants an automated tracking system is more efficient. For toxic or allergic plants an automated tracking may have labor safety advantages. In an environment using artificial intelligence, e.g. deep learning, automated individual tracking of the growth of plants may enable a necessary feedback loop.

Unmanned aerial vehicles have been proposed as means for individual tracking of the growth of plants as well as robots moving on the ground. Drones, however, have a limited time for operation and robots moving on the ground need pathways between the plants.

In scientific environments cable suspended camera systems similar to those known in sports stadiums have been proposed. For example, the article “NU-Spidercam: A large-scale, cable-driven, integrated sensing and robotic system for advanced phenotyping, remote sensing, and agronomic research” in Computers and Electronics in Agriculture, Volume 160, May 2019, Pages 71-81 describes such a system.

U.S. Pat. No. 10,369,693 B1 describes systems, methods, devices, and techniques for controlling and operating cable-suspended robotic systems which may be used also for seeding, fertilizing, irrigation, crop inspection, livestock feeding or other agricultural operations in a pasture, orchard, or field.

CN111425733A describes a wire driven parallel unmanned agricultural robot and a control method thereof. The unmanned agricultural robot comprises a mobile platform, a pillar system, a winding system, at least four wires, an ultrasonic module and a control system.

### SUMMARY OF THE INVENTION

An object of the invention is to provide a robotic sensor and manipulation platform for farming having a robotic base and a robotic sensing and manipulation tip deployable from the robotic base to commanded positions and elevations in a plant growth area. The robotic sensing and manipulation tip having a plurality of sensors adapted to detect and monitor various aspects of plant health and growth conditions, and a computer-based control system configured analyze gathered sensor data and provide analyzed results to the farmer or producer.

Monitoring crop growth in a crop field or greenhouse is a critical and productive task which can productively be offloaded from direct human labor. New sensor and technologies applied in the robotic aerial sensor and manipulation platform presented herein are allow farmers to get a much higher level of data and computer analysis about their crops than they have in the past. The robotic aerial sensor and manipulation platform includes an aerially maneuvered robotic platform base, a sensing and analysis tip and analysis software, which can be configured to operate autonomously in the plant growth area. The farmer or producer can view the collected crop data and analysis in real time.

The aerial sensor and manipulation platform is adapted to provide a more detailed autonomous monitoring of crop growth particularly as the deployable sensing and manipulation tip is configured to get closer to the plants or crops, moving into spaces too small for a human to work, and to get a problem areas, detect plant health problems and resolve issues. The plant spray device tip of the aerial sensor and manipulation platform can be applied for tasks, such as an autonomous targeted application of water, fertilizers, and pesticides onto targeted plants, particularly in response to sensor readings and programmatic analysis of sensor data by the computer-based control system.

Irrigating and fertilizing crops and plants has traditionally used a lot of water, and so is inefficient. The disclosed invention discloses an autonomous computer-controlled robot or robotic aerial sensor and manipulation system having one or a plurality of multiple deployable sensing and manipulation tips providing robotically directed precision irrigation and fertilizer application, amount other things, which can reduce wasted water by only targeting specific plants and reducing waste. Additionally, the sensing and manipulation tip of the aerial robotic sensor and manipulation platform is adapted to autonomously navigate between rows of crops or plants and apply sprays and irrigation directly to the base or targeted leaves of each plant.

The robotic sensor and manipulation platform has the advantage of being able to access plant and growth areas where humans and larger equipment cannot. For example, corn growers face a problem that the plants grow too quickly to reliably fertilize them. The present invention solves this and other problems as it easily moves between the rows of plants and individual neighboring plants and targets nitrogen fertilizer directly at the base of the targeted plants, take sensor readings detecting soil, and, moisture and plant health, apply water, remove damaged growth, aggregate data to determine plant health, detect and resolve insect infestation issues, among other things.

Additionally, spraying pesticides and weed killers onto large plant growth area is not only wasteful but also may be severely harmful to the environment. The robotic sensor and manipulation platform disclosed herein provides a much more efficient method of micro-spraying and can significantly reduce the amount of herbicide used in plant production and farming. The robotic sensor and manipulation platform makes use of use computer vision and feature analysis technology to detect weeds and then spray a targeted micro spray of herbicide onto the weeds.

The robotic sensor and manipulation platform provides a variety of interchangeable sensor manipulation tips, include tips with a pruning or cutting device. Pruning is a time-consuming and complex job for the farmer or operator. The computer-based control system and its algorithms collect and analyze sensor data on plant health and condition and can decide which plant growth to prune, which to keep and which to remove.

Disclosed herein is a robotic sensor and manipulation platform which is configured to connect directly or indirectly onto an aerial support and positioning system and be maneuvered along control system directed paths over ort within the plant canopy. The robotic sensor and manipulation platform generally includes a robotic base connected to and moved to command positions by the aerial support and positioning system. The at least one sensing and manipulation tip is deployable from the robotic base via a tip suspension cable or telescoping collapsible pipe sections under control of a computer-implemented control system. The at least one sensing and manipulation tip is provides with one or more sensors selected from the set: at least one camera taking images, at least one distance sensor detecting distance to nearby plants and objects; at least one temperature sensor detecting ambient air temperature, at least one air quality sensor, at least one airflow sensor, at least one light intensity and/or light spectrum sensor, at least one tip orientation detection means, detecting rotation orientation of the sensing and manipulation tip relative to the robotic base, at least one humidity sensor, at least one CO₂ sensor and/or at least one fluorescence sensor, fluorescence filter or filter cube. robotic sensor and manipulation platform includes a tip positioning mechanism having a motor drive responsive to positioning commands from the control system, the tip positioning mechanism is arranged on the robotic base, supports positions and connects the sensing and manipulation tip to the robotic base. The tip positioning mechanism operable to move the sensing and manipulation tip to commanded positions above or in the plant canopy.

In aspects of the inventive disclosure, the robotic sensor and manipulation platform further includes one or more manipulation attachments configured to detachably connect to the sensing and manipulation tip of the manipulation platform. The one or more manipulation attachments may include at least one of: a cutting device operable by the control system to trim, prune or cut plant material from plants in a geometric plant growth area, a handling device operable by the control system to hold, grasp or stabilize certain areas of a plant while deriving further measurements, a spray device operable by the control system and having one or more directional spray nozzles, at least one needle device operable by the control system to derive plant measurements beneath an outer plant surface, such as plant sap measurements.

The robotic sensor and manipulation platform may include an extensible arm controlled by the control system, the extensible arm having either folding arm sections or a telescoping arm sections, such that individual manipulation attachments may be selectively and detachably connected to the extensible arm under the control of the control system. The one or more manipulation attachments are preferably provided with at least one of the one or more sensors discussed earlier above.

Preferably the sensing and manipulation tip is configured as a bicone without edges, so as to smoothy slide into plant growth without entangling or damage plants.

In some aspects of the inventive disclosure, the spray device has at least one of the one or more directional spray nozzles having a spraying direction controlled by the control system to target areas of plants or soil within the plant grown area.

Preferably, the one or more directional spray nozzles are actuated on/off and spray direction controlled, the spray nozzles preferably controlled individually by the control system.

In another aspect of the inventive disclosure, the at least one sensing and manipulation tip is a plurality of different sensing and manipulation tips configured for different functions, further including at least one sensing and manipulation tip selected from the set of: a cutting device operable by the control system to trim, prune or cut plant material from plants in a geometric plant growth area, a handling device operable by the control system to hold, grasp or stabilize certain areas of a plant while deriving further measurements, a spray device operable by the control system and having one or more directional spray nozzles, at least one needle device to derive plant measurements beneath an outer plant surface, wherein the at least one needle device includes a plant sap measuring device and/or an extensible arm controlled by the control system, the extensible arm having either folding arm sections or a telescoping arm sections. Preferably the plurality of sensing and manipulation tips are individually selectively attached and detachably connected onto the robotic sensor and manipulation platform under control of the control system.

In preferred aspects of the inventive disclosure, the at least one of the one or more directional spray nozzles of the spray device have a spraying direction controlled by the control system. Even more preferred is having the one or more directional spray nozzles individually actuated and controlled by the control system. Preferably the spray nozzles have a controlled spray on, spray off, and/or spray direction, preferably individually.

In various aspects of the inventive disclosure, the robotic sensor and manipulation platform includes a mechanical self-cleaning mechanism configured to wipe clean or wipe-off the tip positioning mechanism, such as tip suspension cables or telescoping pipe sections, while the sensing and manipulation tip is driven upwards towards the robotic base under control of the control system.

In some aspects of the inventive disclosure, the robotic sensor and manipulation platform is provided with a force detection sensor or a visual sensor in communication with the control system and directly detecting or indirectly inferring forces applied on the tip positioning mechanism or the robotic sensor and manipulation platform, so as to detect obstacles encountered or other entanglements of the sensing and manipulation tip in the plants or other obstacles.

In preferred aspects of the inventive disclosure, the sensing and manipulation tip is or includes at least one bicone sensing and manipulation tip having an arcuate, or semi-circular, viewing/sensing slot or window provided in an outer wall of the bicone sensing and manipulation tip. The bicone sensing and manipulation tip having a motor driven rotating disc rotatably mounted in an interior of the in the bicone sensing and manipulation tip. The rotating disc operatively coupled to and controlled by the control system to rotate about an axis of rotation to positions commanded by the control system. The rotating disc arranged in a plane and having an outer circumference substantially aligned or aligned adjacent to a viewing/sensing slot or window of the bicone sensing and manipulation tip. One or more cameras is arranged on and rotated in unison with the rotating disc to position the camera(s), under control of the control system, at desired viewpoint positions along a, arcuate length of the viewing/sensing slot, this under control of the control system. At any point in time, the rotating disc with the camera(s) can be rotated by the control system to expose the lens of the camera and record images at control system commanded viewpoints of interest in locations about or within the plant canopy, such as for detecting insect infestations, disease, or injury areas in plant growth, as well as to determine areas of interest for sensor gathering sensor measurement. The camera images may also be processed to map the plant grown area and plant canopy for determining access paths though or about the plant growth area and to evaluate distances to plants or obstacles, or to infer cable tension or slack in the positioning system.

Advantageously, the arcuate, or semi-circular, viewing/sensing slot or window is preferably arranged substantially in a lower cone portion of the bicone sensing and manipulation tip, such that an upper cone portion of the bicone sensing and manipulation tip has a protected upper region which preferably is substantially enclosed and into which the viewing/sensing slot or window does not extend. At any time, the control system can rotate the rotating disc to move the camera(s) into the protected upper region such that the camera(s) are positioned away from the viewing/sensing slot or window, and thereby protected from dirt and scratches by the bicone housing while deployed in or robotically moving about the plant canopy.

In preferred aspects, the bicone sensing and manipulation tip is rotatably coupled to and affixed to the tip positioning mechanism by a motor driven rotatable pan joint, rotated to commanded positions under the control of the control system. The pan joint is operatively coupled to the control system controlled thereby to rotate the bicone sensing and manipulation tip about an axis of the tip suspension cable or tubular pipe sections of the tip positioning mechanism to enable a controlled full 360-degree field of view from the at least one camera about the axis of the tip suspension cable or tubular telescoping pipe sections. The rotating disc may further include at least one of the one or more sensors discussed herein affixed onto and rotated in unison with the rotating disc.

Also disclosed herein is an aerial robotic sensor and manipulation system having the robotic sensor and manipulation platform, bicone sensing and manipulation tip(s) and other features discussed earlier above in this Summary section. A control system (or computer-based control system) is provided having one or more processors executing instructions stored on a non-volatile data store, wherein the instructions, when executed, by the one or more processors, are configured to autonomously operate the aerial robotic sensor and manipulation system, preferably independent of human oversight or actions. The aerial robotic sensor and manipulation system includes an aerial support and positioning system embodied as either: a plurality of aerial platform positioning cables connected to and driven by a cable spooling device, connected to and supporting the robotic sensor and manipulation platform over or within a plant growth area. The aerial support and positioning system having a motor driven cable spooling device responsive to commands from the control system, the plurality of cable spooling devices are responsive to commands from the control system to controllably deploy or retract lengths of the aerial platform positioning cable to move the robotic sensor and manipulation platform in X and/or Y and/or Z directions above or above or within the plant growth area. A plurality of cable support points are provided, such as, for example, on post or walls, each is fixed onto an elevated support structure at a fixed position preferably above a top of the plant canopy. The cable support points generally delimit in 2D X-Y an outer boundary of a geometric plant growth area, at least the geometric plant growth area accessible to the robotic sensor and manipulation platform.

The aerial support and positioning system may be realized as by a gantry aerial X-Y support and positioning device supporting and positioning the robotic sensor and manipulation platform above the plant growth area and having at, least one drive motor responsive to commands from the control system to move the robotic sensor and manipulation platform in X and/or Y and/or Z directions over the plant growth area to commanded positions.

Preferably at least one aerial platform positioning cable of the plurality of aerial platform positioning cables supporting and positioning the robotic sensor and manipulation platform has an outer sheath which carries and encloses therein one or more electric power conductors, one or more a network or data communication cables, and may include one or more fluid supply tubes, all protectively enclosed within an interior of the at least one aerial platform positioning cable, so as to be wound and unwound from the cable spooling device with the platform positioning cable. In this way the enclosed cables and tubes are supported within the aerial platform positioning cable(s), and are prevented from entanglement in the surrounding environment. The cable supporting the robotic sensing and manipulation tip(s) from the robotic sensor and manipulation platform preferably can be similarly configured.

The aerial robotic sensor and manipulation system may further include a resting platform arranged within the outer boundary of a geometric plant growth area and positioned above the plant canopy, for example in raised platforms supported by posts or walls, or other elevated structures. The resting platform may hold and provide one or more one or more manipulation attachments which are configured to autonomously connect to and detachably connect from the robotic sensor and manipulation platform Preferably the control system controls the detachable connection and the disconnection of the one or more manipulation attachments, for retrieval from the resting platform and return to the resting platform.

In another aspect, the aerial robotic sensor and manipulation system includes at least one force detection sensor or a visual sensor in communication with the control system and detecting forces applied on the tip positioning mechanism or the robotic sensor and manipulation platform for detecting encountered obstacles or entanglements of the sensing and manipulation tip. The at least one distance sensor may be a LiDAR sensor detecting distance to nearby plants and objects.

Finally, other aspects of the invention are directed to methods used by the aerial sensor and manipulation platform for detecting problematic microclimates for scheduling the platform to periodically return to desired locations in an agricultural field for detecting bugs, pest and insects using one or more cameras, sensors and/or other imagers of the aerial sensor and manipulation platform as described herein. Still other methods are provided for detecting bugs, pest and insects using one or more cameras, sensors and/or other imagers of the aerial sensor and manipulation platform as described herein.

### BRIEF DESCRIPTION OF THE DRAWINGS

The accompanying Figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

Features of the present invention, which are believed to be novel, are set forth in the drawings and more particularly in the appended claims. The invention, together with the further objects and advantages thereof, may be best understood with reference to the following description, taken in conjunction with the accompanying drawings. The drawings show a form of the invention that is presently preferred; however, the invention is not limited to the precise arrangement shown in the drawings.

FIG. 1 depicts a schematic view of an aerial robotic sensor and manipulation system installed over and managing plant grown health of a plant growth area, such as a portion of an agricultural field, or arranged within an interior of a plant growth structure, for example a greenhouse, consistent with the present inventive disclosure;

FIG. 1A illustrates, for better understanding, a preferred outer contour of the sensing and manipulation tip having a substantially smooth bicone shaped body without edges and shaped to smoothly pass through the plant growth or a trellis without entangling into or damaging the plants. For understanding, the sensing and manipulation tip is depicted under the plant canopy, managing the growth environment and health of grapes vines in a vineyard, consistent with the present inventive disclosure;

FIG. 2 depicts an enlarged view of the robotic sensor and manipulation platform of FIG. 1, depicting the sensing and manipulation tip deployed from the robotic base and supportively connected to one or more aerial platform positioning cables over a managed plant growth area, consistent with the present inventive disclosure;

FIG. 3 depicts a preferred aspect of the inventions in which at least one of the aerial platform positioning cables enclose electric power conductors, sensor signal lines, data line and/or network cable and a fluid supply line, all enclosed in the interior of the aerial platform positioning cable, consistent with the present inventive disclosure;

FIG. 4. depicts a spray tip variant of the sensing and manipulation tip of FIG. 2, including a plurality of spray nozzles for spraying treatments onto or irrigating plants in the growth area, consistent with the present inventive disclosure;

FIG. 5 is a schematic illustration of the robotic base and a sensor manipulation tip deployably and supportively connected to the robotic base by the tip suspension cable or tubular pipe sections;

FIG. 6, FIG. 7A and FIG. 7B provide a schematic illustrations of a preferred aspect of the invention in which the sensing and manipulation tip includes a rotating disc having one or more sensors and generally aligned with a viewing/sensing slot or window of the sensing and manipulation tip; and

FIG. 8 is a schematic illustration in which the aerial support and positioning system includes a gantry aerial support and positioning device aerially supporting and positioning the robotic sensor and manipulation platform, for example, above a plant growth area.

FIG. 9 is a flow chart diagram illustrating processes used by the aerial sensor and manipulation platform for detecting problematic microclimates and periodically returning to desired locations in the plant growth area.

FIG. 10 is a flow chart diagram illustrating processes for detecting bugs, pests, and insects using one or more cameras, sensors and/or other imagers as used in the aerial sensor and manipulation platform described herein.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method steps and apparatus components related to an autonomous computer controlled robotic aerial sensor and manipulation platform having exchangeable deployable sensing tips for farming. Accordingly, the apparatus components have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

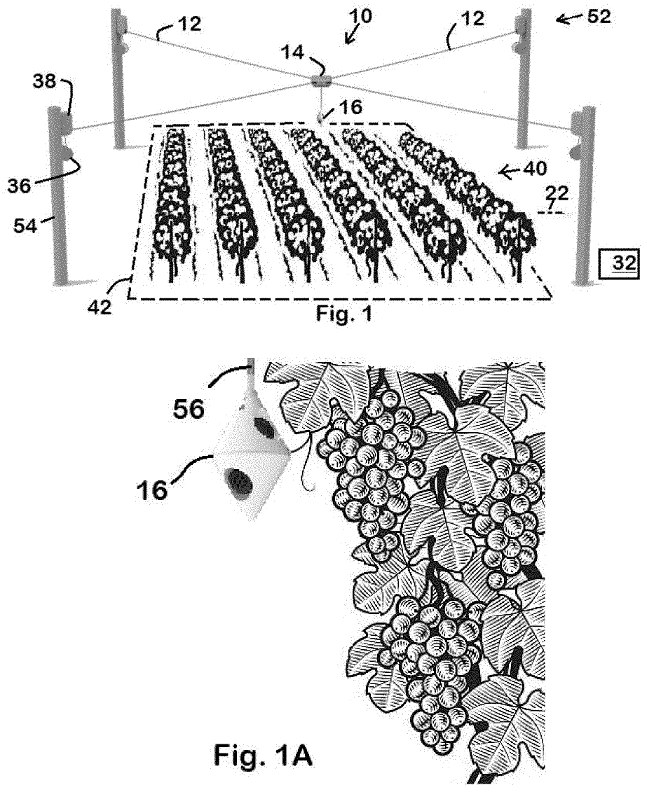

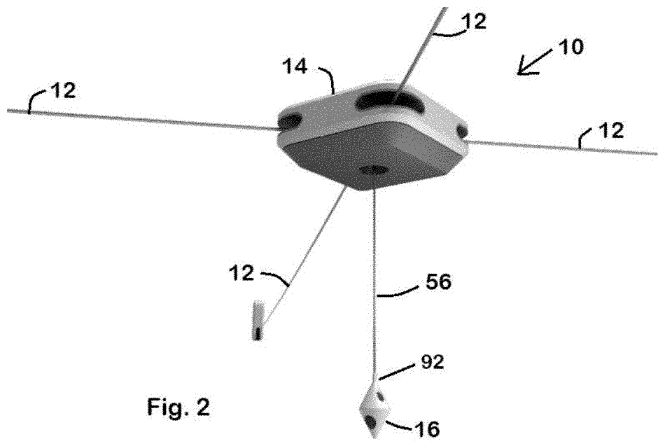

FIGS. 1 and 2 depict a schematic view of an aerial robotic sensor and manipulation system 52 installed over and operable to monitor and manage the plan growth environment and plant health of plant growth area 40 (FIG. 1). The illustration of FIG. 1 is to be understood as representing either an outdoor growing area, such as a portion of an agricultural crop-production field or arranged within an interior of a plant growth structure, for example a greenhouse.

FIG. 2 provides an enlarged view of the robotic base 14 of FIG. 1 suspended in the air by 4 aerial platform positioning cables 12 and provided with a bicone-shaped sensing and manipulation tip 16 deployed below the robotic sensor and manipulation platform 10, suspended on a tip suspension cable 56 or telescoping pipe sections from the robotic base 14. The aerial robotic sensor and manipulation system 52 is shown in FIGS. 1 and 2 arranged in service over the plant growth area 40.

A plurality of cable support points 38 are each securely fixed onto an elevated support structure 54 positioned about 4 corners of the plant growth area 40 and positioned at above the plant canopy of the plant growth area 40. The plurality of cable support points 38 are arranged outwardly away from the outer boundary 42 of the plant growth area 40 as a sufficient distance such that the robotic sensor and manipulation platform 10 reach all portions of the plant growth area 40. The cable support points 38 are each provided with cable spooling devices 36 and, in this illustration, shown arranged on the elevated support structure 54. In FIG. 1, the elevated support structure is shown a vertical pole, columns or a build wall arranged about the corners of the plant growth area 40. Advantageously, the cable spooling devices 36 are responsive to positioning commands from a control system 32 to effect a controlled spooling or despooling of lengths of the platform positioning cable 12 from the cable spooling devices 36 so as to move and reposition the robotic base 14 along a desired path to a desired position over the plant growth area 40.

The cable support points 38 are arranged at or outwardly from the 2D X-Y outer boundary 40 of the geometric plant growth area.

The cable spooling devices 36 preferably include an encoder in communication with the control system 32, the encoders changes in the deployed cable lengths such that the control system can coordinate the spooling and despoiling of the four cable spooling devices to achieve a desired travel path, robotic base elevation and cable tensioning of the aerial platform positioning cables.

In FIGS. 1 and 2, each platform positioned cable 12 has an end attached onto the robotic base (one at each corner) and tensioned by the cable spooling devices 36 such that the robotic base 12 is supported at a commanded elevation above the plant canopy 22 by commanded spooling and de-spooling movements of the cable drums of the cable spooling devices 36.

As can be readily appreciated, the control system coordinated spooling and despoiling movements of each of the cable spooling devices 36 are necessarily coordinated by the control system 32, to successfully move the robotic base 14 along the desired path above the plant canopy 22 to the commanded position and elevation.

A tip positioning mechanism 20 is arranged in the robotic base and is responsive to commands from the control system to deploy the sensing and manipulation tip 16 at a control system commanded position below the robotic base 14.

The tip positioning mechanism 20 may be embodied as a cable supportively connecting the robotic base 14 to the sensing and manipulation tip 16, or alternately may be embodies as a plurality of tubular telescoping pipe sections 50 that extend from or collapse into each other, the tubular pipe sections retractable into each other so as to adjust an overall length of the tubular telescoping pipe sections to deploy the sensing and manipulation tip 16 at a control system commanded position below the robotic base 14.

As best seen in FIG. 1A, the sensing and manipulation tip 16 preferably has a smooth bicone shaped body or a may have a drop shaped body. In general, the drop shaped body is similar to a bicone but has a lower half or portion of the body shaped as a bottom half of a sphere, for example, forming a shape this is somewhat similar to a water drop, the body having an outer surface without edges shaped to smoothly pass-through plant growth or a trellis without becoming entangled or damaging the plants. As shown on FIG. 1A, the sensing and manipulation tip 16 is deployed below the robotic base 12 at an elevation controlled by the control system 32 and supported on the retractable, extendable tip suspension cable 56.

As seen in FIG. 2, the platform base 10 preferably has outer surfaces which are smoothly rounded, preferably avoiding sharp. The platform positioning cables 12 are fixedly connected to respective corners of the platform base 10 and are tensioned by the cable spooling devices 36 to support the platform base 10 at a desired elevation and to move the platform base 10 along a commanded path to a commanded position above the plant growth area 40.

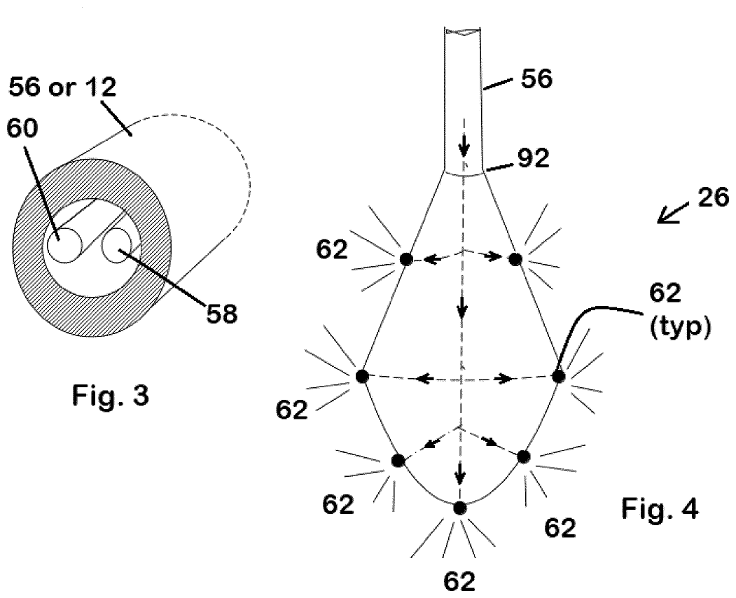

FIG. 3 schematically depicts a cross-section of a preferred configuration of the aerial platform positioning cable 12 in which sensor signal lines, data line and/or network cables 60 and at least one fluid supply line 58 is enclosed in the interior of the aerial platform positioning cable 12. In this way, the fluid supply lines, signal lines etc. are embedded into the interior of the cable and are not dangling in the air to become entangled in and possibly damage the growing plants of the plant growth area 40.

FIG. 4 schematically depicts a spray device tip 26 as advantageous variant of the sensing and manipulation tip 16 of FIG. 2, in this case a spray device tip 26 having a plurality of spray nozzles 26 configured for spraying treatments or irrigating plants in the growth area. In some aspects of the invention, the spray nozzles 26 are individually controlled on/off or optionally throttled by the control system to produce and target a controlled spray pattern into a desired location and in a desired direction, for example, onto the underside of a plant leaf or at the plant base or plant roots. The spray nozzles are in fluid communication with the one or more fluid spray lines 58 to deliver insecticides, nutrients, water and/or fertilizers, for just a few examples. FIG. 4 further illustrated that the sensing and manipulations tips may optionally be configured to have can have other smooth outer shapes without edges, forming a modified bicone or drop shaped body. In FIG. 4, the drop shaped body is a smooth substantially hemispherical or parabolic shaped bottom section having a partially elliptical or parabolic cross-section is provided on the bottom of the spray device tip 26.

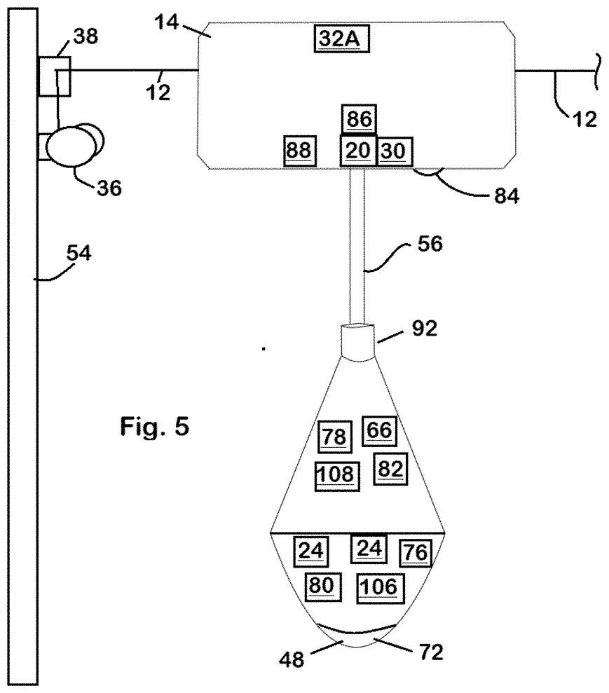

FIG. 5 is a schematic illustration of the robotic base 14 and a sensor manipulation tip 16 deployably connected to the robotic base 14 by the tip suspension cable or tubular pipe sections 56. The base portion of the sensor manipulation tip 16 may include a light distance and ranging (LiDAR) distance sensor 48 in communication with the control system 32, the control system 32 comprising a robotic platform resident control system 32A in communication with and cooperatively interacting with a “compute box” having or including a computer control system 32B. The computer control system 32B is preferably in communication with internet cloud services performing further data analysis, reporting and data storage and communication with farmers and/lor greenhouse operators.

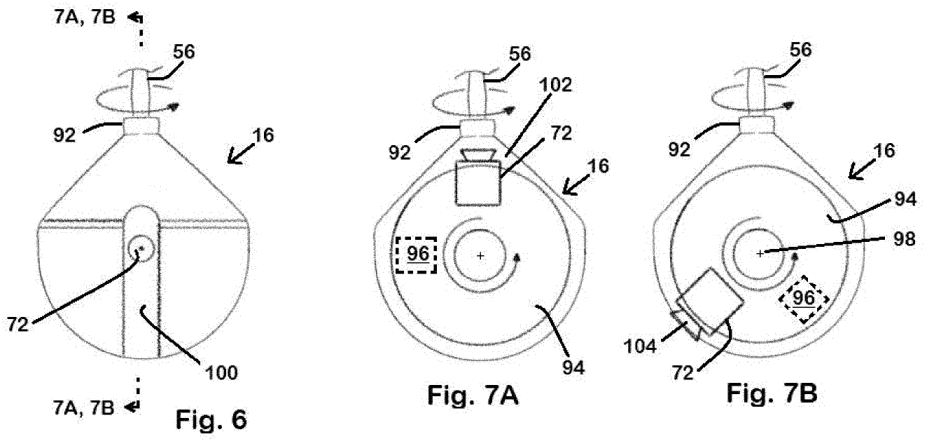

FIG. 6, FIG. 7A and FIG. 7B provide schematic illustrations of a preferred aspect of the invention in which the sensing and manipulation tip 16 includes a rotating disc 94 having one or more sensors and generally aligned with a viewing/sensing slot or window 100 extending through a wall of the housing of the bicone sensing and manipulation tip 16.

As shown in FIGS. 6, 7A and 7B, in a preferred aspect of the invention, the sensing and manipulation tip includes a rotating disc 94 rotatably mounted in an interior of the in the sensing and manipulation tip 16. The rotating disc 94 is operatively coupled to the computer-based control system 32 and controlled to rotate about an axis of rotation 98 to positions commanded by the computer-based control system 32. Generally aligned with the rotating disc 94 is a arcuate, preferable semi-circular, viewing/sensing slot or window 100 provided in the sensing and manipulation tip 16.

One or more cameras 72 for capturing images are arranged on and are rotated in unison with the rotating disc 94 to position the camera(s) 72 and lenses 104 at desired viewpoint positions along a length of the viewing/sensing slot. At any point in time, the rotating disc 94 with the camera(s) 72 can be rotated to expose the lenses 104 and record images from the respective viewpoints of interest above, about or within the plant canopy 22.

Advantageously, at any point in time, for example when the sensing and manipulation tip 16 is lowered into the plant canopy 22, the computer-based control system 32 may rotate the rotating disc 94 to move the camera(s) 72 into the protected upper region 102 such that the camera(s) are positioned away from the viewing/sensing slot or window 100. In this way, the camera(s) 72 can be protected from dirt and scratches while deployed in or robotically moving about the plant canopy 22.

As discussed earlier, the bicone sensing and manipulation tip 16 may be rotatably coupled to the tip suspension cable or tubular telescoping pipe sections 56 by a pan joint 92. The pan joint 92 is operatively coupled to the computer-based control system 32 and controlled to rotate the sensing and manipulation tip 16 about an axis of the tip suspension cable or tubular telescoping pipe sections 56. In this way the sensing and manipulation tip 16 can be rotated to enable a full 360 deg field of view about the axis of the tip suspension cable or tubular telescoping pipe sections 56.

Advantageously, the rotating disc 94 may further have arranged thereon any one of or a variety of the sensors 96 (shown schematically) discussed herein or below, for example: the distance sensor(s) or LiDAR sensor(s) 48, air flow sensor(s) 78, air quality sensors 80, light intensity and/or light spectrum sensor(s) 82, humidity sensor 106, CO₂ sensor(s) 76, fluorescence sensor 90, for example, or other sensors as would be known to those of skill in the art. The sensors 96 may be arranged at any variety of positions on the rotating disc 94.

As discussed previously, it is important to note that any one of or multiple of the sensors may alternately or additionally be arranged within or on the housing of the sensing or manipulation tip 16 rather than being arranged on the rotating disc 94.

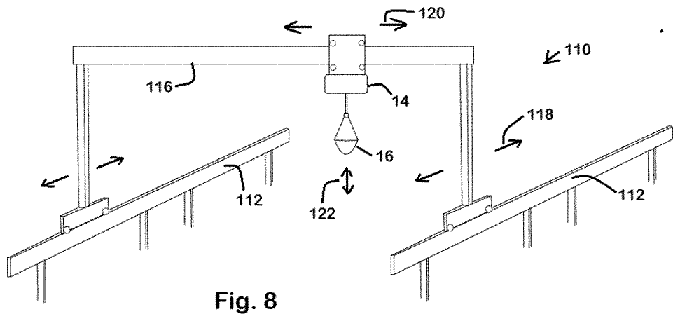

FIG. 8 is a schematic illustration in which the aerial support and positioning system of the robotic sensor and manipulation platform 10 is embodied as a gantry aerial support and positioning device 110, aerially supporting and positioning the robotic sensor and manipulation platform 10 above a plant growth area. The gantry aerial support and positioning device 110 having a plurality of longitudinal rails 112 on which a bridge member 116 is configured to be moved to control system commanded positions along the longitudinal rails 112 in the longitudinal direction 118. The longitudinal rails 112 and/or the bridge member 116 are provided with at least one motor drive responsive to commands from the computer-based control system to move and position bridge member 116 in the longitudinal direction 118 on the longitudinal rails 112. The robotic base 14 of the robotic sensor and manipulation platform 10 is connected to and supported on the bridge member 116. The bridge member 116 includes a motor drive responsive to commands from the computer-based control system to move/reposition the robotic base 14 in the transverse direction 120 to command positions along the bridge member 116. As discussed earlier, the tip positioning mechanism 20 of the robotic base 14 is responsive to commands from the computer-based control system to move the sensing and manipulation tip 16 in the vertical or Z direction 122 into commanded positions above or within the plant growth area.

The LiDAR sensor 48 is a scanner utilizing pulsed light energy emitted from a rapidly firing laser. The light travels to the ground, plant leaf, or other obstacles and is reflected off objects such as branches, leaves, etc. The reflected light energy then returns to the LiDAR sensor where it detected and processed by the computer-based control system 32 to determine distances from the sensor manipulation tip 16 to neighboring objects or obstacles. The LiDAR sensor or scanner can determine the distance between itself and an object by monitoring how long it takes a pulse of light to bounce back. The concept is similar to radar, except using infrared light rather than radio waves. While radar is designed to be used across greater distances, LiDAR generally works over shorter distances, due to the way light is absorbed by objects in its path. By sending, for example, hundreds of thousands of light pulses every second, the LiDAR sensor or scanner can advantageously determine distances and object sizes with relative accuracy over the relatively small distances in a plant growth area.

As an alternate to or in addition to a LiDAR distance sensor, Time-of-Flight multizone ranging sensor might be used.

The sensor manipulation tip 16 preferably includes one or more temperature sensors 66, particularly for sensing air temperatures and temperature variations within the geometric plant growth area 40, detecting a 2D or 3D profile of how temperature changes across the plant growth area 40, such that the control system 32 can adjust temperatures of air cooling or air heating units above or about the plant growth area 40. For example, standard industry type infrared arrays might be used as temperature sensor, allowing for a measurement of not just the environmental temperature but the temperature of a plant and even the temperature distribution on a plant.

The sensor manipulation tip 16 preferably includes one or more cameras taking images and may also serve as a distance sensor, for example by measuring changes in the focal length of the image, or the camera may be embodied to take stereo images from which distance can be calculated by triangulation methods. One or more cameras, as enabling non-limiting examples: Arducam™ 12 MP or Luxonis OAK-1-PCBA™ might be included in the sensor manipulation tip 16. The camera might be integrated, e.g. on a PCB, with chips performing AI modules directly on-board. The cameras might be equipped with autofocus systems for distance measurements.

The robotic base 14 and/or robotic sensor and manipulation tip 16 preferably includes one or more hyperspectral sensors 74. Hyperspectral sensors are devices which record images using a wide portion of the electromagnetic spectrum. These sensors capture an image in a number of slices or spectral bands, each representing a portion of the spectrum. These spectral bands may then be combined to form a three-dimensional composite image. The resultant images or hyperspectral cubes provide data for a definitive, deep layer analysis of the plant materials or minerals which make up the scanned area. Hyperspectral imaging is known to be a valuable diagnostic tool in agricultural crop monitoring applications and mineralogy fields. Hyperspectral sensors may be applied with the control system 32 to create images and predictive reports which may assist in the early detection of plant disease outbreaks and overall plant health. Hyperspectral sensors can also be applied with the control system 32 to measure and determine nutrient levels in standing crops and water levels in the surrounding soil.

The robotic base 14 and/or the robotic sensor and manipulation tip 16 may include one or more CO₂ sensors, detecting carbon dioxide levels in the ambient air in the plant growth area 40. E.g. CO₂ sensors, such as for example Sensirions SCD4x™ or combined sensors for CO₂ and temperature and/or humidity like Sensirions SCD30™ might be used.

The robotic base 14 and/or the robotic sensor and manipulation tip 16 may include one or more airflow sensors 78, detecting air flow speed and/or direction in the plant growth area 40. E.g. Hot wire anemometers might be used, in particular in indoor environments, and a spinning cup anemometer might be used, in particular in outdoor environments.

The robotic base 14 and/or the robotic sensor and manipulation tip 16 may include one or more air quality sensors 80, for example: particulate sensors (PM 2.5, PM 5), TVOC (total volatile organic compound) sensors, humidity sensors, ozone sensors, and CO₂ sensors (as above), as well as other air quality sensors as would be known to those skilled in the art. An example for such a sensor is the Bosch™ BME 680 which can measure humidity, barometric pressure, temperature, and additionally it contains a MOX sensor. The heated metal oxide changes resistance based on the volatile organic compounds (VOC) in the air, so it can be used to detect gasses and alcohols such as Ethanol, Alcohol and Carbon Monoxide, and perform air quality measurements.

The robotic base 14 and/or the robotic sensor and manipulation tip 16 may include light intensity and light spectrum sensors 82. Such sensors might be highly specialized (Extended) Photosynthetically Active Radiation Sensors or rather standard sensors e.g. like the Adafruit™ RGB color sensor TCS34725 or a multi-channel spectral color sensor. For some applications one or more sensors to capture the full spectrum combining visual light, near infrared and mid infrared may be advantageous.

The robotic base 14 and/or the robotic sensor and manipulation tip 16 may include pan tilt camera unit 84, preferably rotatable by 360 degrees freely or by 180 degrees in both directions.

The robotic base 14 preferably includes an air pressurization mechanism 86, for example, an air compressor device. The air pressurization mechanism 86 is responsive to commands from the control system 32 to pressurize, on command, an interior channel in the tip suspension cable 56 so as to stiffen the cable against flexing so as to positionally stabilize the robotic sensor and manipulation tip 16 against swinging or deflection relative to the robotic base 14. This can be especially important when spraying or pruning plants.

The pan/tilt camera unit 84 and other cameras of the robotic base 14 and/or the robotic sensor and manipulation tip 16 are operable by the control system 32 as another means to detect undesirable swinging or movement of the robotic sensor and manipulation tip 16 such as to initiate the air pressurization mechanism 86.

The robotic base 14 and/or the robotic sensor and manipulation tip 16 may preferably include at least one tip orientation detection means 88, detecting rotational orientation of the robotic sensor and manipulation tip 16 relative to the robotic base 14. The rotational orientation of the robotic sensor and manipulation tip 16 relative to the robotic base 14 may also be detected by the pan tilt camera 84 of the robotic base 14.

The robotic base 14 and/or the robotic sensor and manipulation tip 16 may preferably include at least one motion sensor 108, e.g. a combined accelerometer, an accurate close-loop triaxial gyroscope, a triaxial geomagnetic sensor as known e.g. from smart phones.

The robotic sensor and manipulation tip 16 preferably may include at least one fluorescence sensor 90 operative to study chlorophyll and to measure dissolved oxygen concentrations. The at least one fluorescence sensor 90 detects chlorophyll fluorescence (CF) data and communicates with the control system 32 to provide a vital understanding plant health and crop photosynthesis. In some embodiments, the at least one fluorescence sensor 90 collects image data at high resolution across the chlorophyll fluorescence emission spectrum, preferably from 670 to 780 nm, preferably to allow both the ‘Oxygen-A’ and ‘Oxygen-B’ bands to be measured for more accurate insight into plant photosynthetic processes. The at least one fluorescence sensor 90 is preferably rotatable at up to 360 degrees about the robotic sensor and manipulation tip 16.

The tip positioning mechanism 20 of the robotic base 14 may include a force detection sensor 30 in communication with the control system 32 and detecting forces applied on the tip positioning mechanism 20, tip suspension cable 56 or the robotic sensor and manipulation tip 16 for detecting encountered obstacles or entanglements of the robotic sensing and manipulation tip 16. In some embodiments, the force detection sensor 30 may be a motor current sensor, detecting variations or increases in motor current draw of the tip positioning mechanism 20 indicating entanglement.

Those skilled in the art will recognize that all sensors described herein are in communication with the computer-based control system 32, providing sensor data to the control system 32 for plant health analysis, 3D model generation of the plant growth area, generation a 3D topology of the plant growth area and to enable the autonomous, automated operation of the robotic base 14 and the robotic sensor and manipulation tip 16 as well as the reporting functions of the compute box/computer control system 32B and cloud provided services.

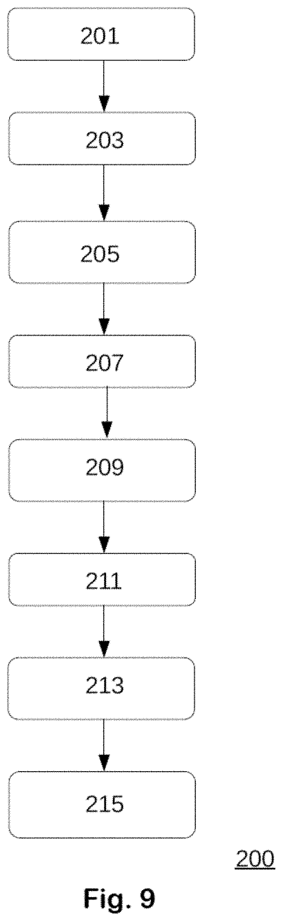

FIG. 9 is a flow chart diagram illustrating various processes used by the aerial sensor and manipulation platform for detecting problematic microclimates enabling the platform to be scheduled to periodically return to desired locations above the plant growth area. The methods 200 includes, but are not limited to, the step of detecting 201 one or more microclimates in the in the plant growth area over some predetermined time period. Those skilled in the art will recognize that a microclimate is the climate of a very small or restricted area, especially when this differs from the climate of the surrounding area. This is accomplished by first coarsely sampling 203 the plant canopy space and compilating and/or collecting 205 these measurements at all measured locations.

Critical areas whose climate exceeds various predetermined standards such as temperature, humidity and light intensity or where the change rate exceeds predetermined standards are identified 207. For example, a predetermined standard in a plant growth area may be measured several times with predetermined time intervals, e.g one day, and thus zones of the plant growth area with a high volatility of the standard may be determined. Once identified, critical areas are further measured 209 by taking additional subsamples so that more information and more specific or “dense” geographic areas can be identified. The subsamples and compiled where the resulting data is used to produce and compute 211 a heat map of the local environment. The map can then be used by the aerial sensor and manipulation platform enabling it to return 213 to the areas having larger or faster variations, e.g. in temperature, humidity or light intensity, at a more frequent interval. After each visit, the heatmap can be updated with new data. Hence, the aerial sensor and manipulation platform can be scheduled to visit these microclimate locations for additional visits providing new or additional applications of water, fertilizers, and/or pesticides.

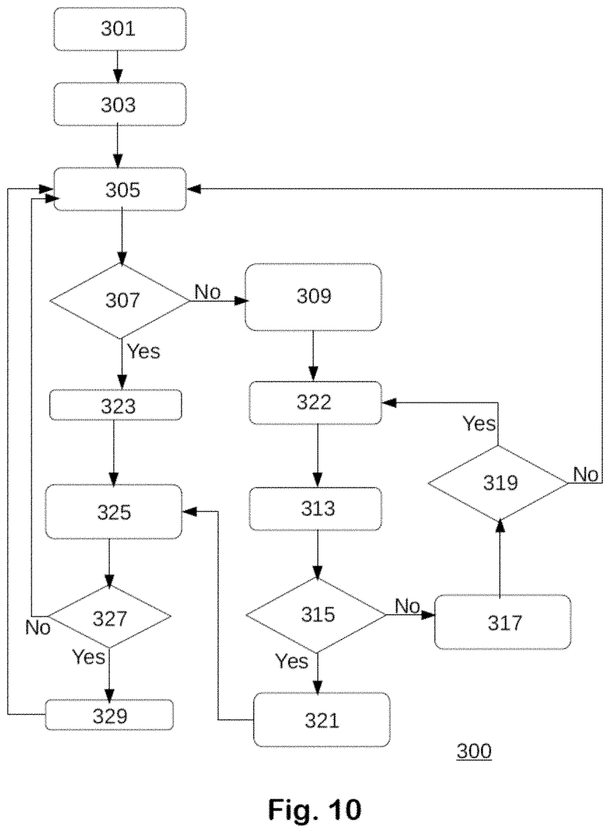

FIG. 10 is a flow chart diagram illustrating a process for detecting bugs, pests and insects using one or more cameras, sensors and/or other imagers used in the aerial sensor and manipulation platform as described herein. The pest detection method 300 includes the steps of checking 302 for pests in the plant canopy. The various locations that are to be checked are compiled 303 to determine a path to that location 305. If the target location is above the canopy, then the sensor is moved 323 to that location and the camera pointed in the desired direction 325. If pests are present, then their quantity and type can be identified and reported 327 for further action.

In situations where the target location is not above the canopy 307, a new location above the target location is computed 309. The aerial senor and manipulation platform is moved to that new target location and sensors are used to detect 313 any impediments or obstacles. If the location is not accessible 315, then the sensor measurements are evaluated 317 to determine if there is any viable free space. If there are no alternatives, then the process starts again, where the path to the next location is computed 305. If an alternative is available, then the sensor is moved to that location 311 and the process continues.

When the location is determined as accessible 315, then the sensor platform can be moved and/or lowered into position 321. Thereafter, a camera, sensor or other imaging device is pointed in a requested direction and an image is captured 325. A determination can then be made if pests are present 327. If no pests are present, then the next location is computed and the process continues. However, if pests are present, then the presence of the pest, the quantity and type of pest of can be reported for applications of pesticides or other further action.

Thus aspects of the present invention are directed a robotic sensor and manipulation platform and methods of use that are configured to connect directly or indirectly to an aerial support and positioning system. The platform includes a robotic base connected to and moved to command positions by the aerial support and positioning system and at least one sensing and manipulation tip deployable from the robotic base that includes one or more sensors for imaging and detecting climatic data and parameters. A motor driven tip positioning mechanism is responsive to positioning commands from a control system. The tip positioning mechanism arranged on the robotic base and connecting the sensing and manipulation tip to the robotic base and is operable operable to move the sensing and manipulation tip to desired positions above or in the plant canopy.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of the present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

What is claimed is:

1. A robotic sensor and manipulation platform configured to connect directly or indirectly to an aerial support and positioning system, the robotic sensor and manipulation platform comprising:
a robotic base connected to and moved to command positions by the aerial support and positioning system;
at least one sensing and manipulation tip deployable from the robotic base, comprising:
one or more sensors selected from the set:
at least one camera taking images;
at least one distance sensor detecting distance to nearby plants and objects;
at least one temperature sensor;
at least one air quality sensor;
at least one airflow sensor,
at least one light intensity and/or light spectrum sensor;
at least one tip orientation detection means, detecting rotation orientation of the sensing and manipulation tip relative to the robotic base; and
at least one humidity sensor;
at least one CO₂ sensor;
at least one fluorescence sensor, fluorescence filter or filter cube;
a tip positioning mechanism having a motor drive responsive to positioning commands from a control system, the tip positioning mechanism arranged on the robotic base and connecting the sensing and manipulation tip to the robotic base, the tip positioning mechanism operable to move the sensing and manipulation tip to commanded positions above or in the plant canopy.

2. The robotic sensor and manipulation platform according to claim 1, further comprising:
one or more manipulation attachments configured to detachably connect to the sensing and manipulation tip of the manipulation platform,
the one or more manipulation attachments include at least one of:
a cutting device operable by the control system to trim, prune or cut plant material from plants in a geometric plant growth area;
a handling device operable by the control system to hold, grasp or stabilize certain areas of a plant while deriving further measurements;
a spray device operable by the control system and having one or more directional spray nozzles;
a needle device operable by the control system to derive plant measurements beneath an outer plant surface, wherein the needle device includes a plant sap measuring device;
an extensible arm operable by the control system, the extensible arm having either folding arm sections or a telescoping arm sections, wherein one or more manipulation attachments are selectively and detachably connected to the extensible arm under control of the control system.

3. The robotic sensor and manipulation platform according to claim 2, wherein
the one or more manipulation attachments are provided with at least one of the one or more sensors of claim 1.

4. The robotic sensor and manipulation platform according to claim 2, wherein
at least one of the one or more directional spray nozzles is configured to have a controlled spraying direction controlled by the control system.

5. The robotic sensor and manipulation platform according to claim 4, wherein
the one or more directional spray nozzles are individually actuated and controlled by the control system.

6. The robotic sensor and manipulation platform according to claim 1, wherein
the at least one sensing and manipulation tip is a plurality of functionally different and exchangeable sensing and manipulation tips, further including at least one sensing and manipulation tip selected from the group consisting of:
a cutting device operable by the control system to trim, prune or cut plant material from plants in a geometric plant growth area;
a handling device to hold, grasp or stabilize certain areas of a plant while deriving further measurements;
a spray device having one or more directional spray nozzles;
a needle device to derive plant measurements beneath an outer plant surface, wherein the needle device includes a plant sap measuring device; and
an extensible arm controlled by the control system, the extensible arm having either folding arm sections or a telescoping arm sections;
wherein the plurality of sensing and manipulation tips are each selectively and detachably from the robotic sensor and manipulation platform under control of the control system such that a different one of the plurality of sensing and manipulation tips is then selectively connected onto the robotic sensor and manipulation platform under control of the control system.

7. The robotic sensor and manipulation platform according to claim 6, wherein
at least one of the one or more directional spray nozzles are configured to have a controlled spraying direction controlled by the control system.

8. The robotic sensor and manipulation platform according to claim 7, wherein
the one or more directional spray nozzles are each actuated and controlled individually by the control system, having controlled spray on, spray off and/or spray direction controlled by the control system.

9. The robotic sensor and manipulation platform according to claim 1, further including:
a mechanical self-cleaning mechanism configured to wipe clean or wipe-off the tip positioning mechanism while it drives upwards towards the robotic base.

10. The robotic sensor and manipulation platform according to claim 1, further comprising:
a force detection sensor or a visual sensor in communication with the control system and detecting forces applied on the tip positioning mechanism or the robotic sensor and manipulation platform for detecting encountered obstacles or entanglements of the sensing and manipulation tip.

11. The robotic sensor and manipulation platform according to claim 1, wherein
at least one of the sensing and manipulation tips is a bicone sensing and manipulation tip having an arcuate, or semi-circular, viewing/sensing slot or window provided in an outer wall of the bicone sensing and manipulation tip, the robotic sensor and manipulation platform further comprising:
a rotating disc rotatably mounted in an interior of the in the bicone sensing and manipulation tip, the rotating disc operatively coupled to and controlled by the control system to rotate about an axis of rotation to positions commanded by the control system;
wherein the rotating disc is rotated in a plane substantially aligned with or proximate to the viewing/sensing slot or window of the bicone sensing and manipulation tip;
at least one of the at least one camera is arranged on and is rotated in unison with the rotating disc to position the at least one camera at control system commanded viewpoint positions along an arcuate length of the viewing/sensing slot, under control of the control system;
wherein, at any point in time, the rotating disc with the at least one camera can be rotated by the control system to expose the at least one camera and record images at the commanded viewpoint positions in locations about or within the plant canopy.

12. The robotic sensor and manipulation platform according to claim 11, wherein
the arcuate, or semi-circular, viewing/sensing slot or window is arranged substantially in a lower cone portion of the bicone sensing and manipulation tip;
wherein an upper cone portion of the bicone sensing and manipulation tip has a protected upper region which is substantially enclosed and into which the viewing/sensing slot or window does not extend;
wherein, at any time, the control system can rotate the rotating disc to move the at least one camera into the protected upper region such that the at least one camera is positioned away from the viewing/sensing slot or window, and thereby protected from dirt and scratches while deployed in or robotically moving about the plant canopy.

13. The robotic sensor and manipulation platform according to claim 11, wherein
the bicone sensing and manipulation tip is rotatably coupled to the tip positioning mechanism by a pan joint which is responsive to the control system to rotate to commanded positions under control of the control system, the pan joint operatively coupled to the control system and controlled thereby to rotate the bicone sensing and manipulation tip about an axis of a tip suspension cable or tubular pipe sections of the tip positioning mechanism to enable a full 360 degree field of view from the at least one camera about the axis of the tip suspension cable or tubular telescoping pipe sections.

14. The robotic sensor and manipulation platform according to claim 11, wherein
the rotating disc further includes at least one of the one or more sensors arranged thereon and rotated in unison with the rotating disc.

15. An aerial robotic sensor and manipulation system, comprising:
a control system comprising one or more processors executing instructions stored on a non-volatile data store, wherein the instructions, when executed by the one or more processors, the control system is configured to autonomously operate the aerial robotic sensor and manipulation system;
an aerial support and positioning system comprising:
either:
a plurality of aerial platform positioning cables each connected to and driven by a cable spooling device, the plurality of aerial platform positioning cables connected to and aerially supporting a robotic sensor and manipulation platform over or within a plant growth area, wherein the cable spooling device is motor driven cable, connected to, controlled by and responsive to commands from the control system;
wherein the plurality of cable spooling devices are responsive to commands from the control system to controllably deploy or retract spooled lengths of the aerial platform positioning cable; and
a plurality of cable support points carrying and supporting the platform position cables above the plant canopy, each cable support point fixed onto an elevated support structure at a fixed position above a top of a plant canopy, the cable support points arranged about or delimiting a 2D X-Y an outer boundary of a geometric plant growth area;
or:
a gantry aerial support and positioning device supporting and positioning the robotic sensor and manipulation platform above the plant growth area and having at, least one drive motor responsive to commands from the control system to move the robotic sensor and manipulation platform in X and/or Y and/or Z directions over the plant growth area to commanded positions;
the aerial robotic sensor and manipulation system further comprising:
a robotic sensor and manipulation platform connected onto,
supported by and positioned by the aerial support and positioning system along control system commanded motion paths in an X-direction and/or Y-direction and/or Z-direction over the geometric plant growth area;
wherein the robotic sensor and manipulation platform comprises:
a robotic base connected to and moved to command positions by the aerial platform positioning cables or the gantry aerial X-Y support and positioning device;
at least one sensing and manipulation tip deployable from the robotic base, comprising one or more sensors selected from the set:
at least one camera taking images;
at least one distance sensor detecting distance to nearby plants and objects;
at least one temperature sensor;
at least one air quality sensor;
at least one airflow sensor;
at least one light intensity and/or light spectrum sensor;
at least one tip orientation detection means, detecting rotational orientation of the sensing and manipulation tip relative to the robotic base;
at least one humidity sensor;
at least one CO₂ sensor; and
at least one fluorescence sensor, fluorescence filter or filter cube;
a tip positioning mechanism having a motor drive responsive to positioning commands from the control system, the tip positioning mechanism arranged on the robotic base and connecting the sensing and manipulation tip to the robotic base, the tip positioning mechanism operable under commands from the control system to move the sensing and manipulation tip in a substantially vertical or Z direction relative to the robotic base to commanded positions above or within the plant canopy.

16. The aerial robotic sensor and manipulation system according to claim 15, wherein
at least one aerial platform positioning cable of the plurality of aerial platform positioning cables has an outer sheath which carries and encloses therein at least one of:
at least one electric power conductors
at least one network or data communication cable;
at least one fluid supply tube, protectively enclosed within an interior of the at least one aerial platform positioning cable, so as to be wound and unwound from the cable spooling device with the platform positioning cable.

17. The aerial robotic sensor and manipulation system according to claim 15, further comprising:
a resting platform arranged within or adjacent to the outer boundary of a geometric plant growth area and positioned at or above the plant canopy, the resting platform comprising:
one or more exchangeable manipulation attachments configured to detachably connect to the robotic sensor and manipulation platform;
wherein the control system controls the detachable connection and disconnection of the one or more manipulation attachments.

18. The aerial robotic sensor and manipulation system according to claim 15, further comprising:
one or more manipulation attachments configured to detachably connect to the sensing and manipulation tip of the manipulation platform,
the one or more manipulation attachments include at least one of:
a cutting device operable by the control system to trim, prune or cut plant material from plants in a geometric plant growth area;
a handling device operable by the control system to hold, grasp or stabilize certain areas of a plant while deriving further measurements;
a spray device operable by the control system having one or more directional spray nozzles;
a needle device operable by the control system to derive plant measurements beneath an outer plant surface, wherein the needle device includes a plant sap measuring device;
an extensible arm operable by the control system having either folding arm sections or a telescoping arm sections, wherein one or more manipulation attachments are selectively and detachably connected to the extensible arm under control of the control system.

19. The aerial robotic sensor and manipulation system according to claim 18, wherein
the one or more manipulation attachments are provided with at least one of the one or more sensors of claim 15.

20. The aerial robotic sensor and manipulation system according to claim 18, wherein
at least one of the one or more directional spray nozzles have a controlled spraying direction which is controlled by the control system.

21. The aerial robotic sensor and manipulation system according to claim 20, wherein
the one or more directional spray nozzles are actuated by and controlled individually by the control system.

22. The aerial robotic sensor and manipulation system according to claim 15, wherein
the at least one sensing and manipulation tip is a plurality of sensing and manipulation tips, further including at least one sensing and manipulation tip selected from the group consisting of:
a cutting device operable by the control system to trim, prune or cut plant material from plants in a geometric plant growth area;
a handling device operable by the control system to hold, grasp or stabilize certain areas of a plant while deriving further measurements;
a spray device operable by the control system having one or more directional spray nozzles;
a needle device operable by the control system to derive plant measurements beneath an outer plant surface, wherein the needle device includes a plant sap measuring device; and
an extensible arm controlled by the control system, the extensible arm having either folding arm sections or a telescoping arm sections;
wherein the plurality of sensing and manipulation tips are individually selectively and detachably connected onto the robotic sensor and manipulation platform under control of the control system.

23. The aerial robotic sensor and manipulation system according to claim 22, wherein
at least one of the one or more directional spray nozzles are provided with a controlled spraying direction controlled by the control system.

24. The aerial robotic sensor and manipulation system according to claim 23, wherein
the one or more directional spray nozzles are each actuated and controlled individually by the control system, having controlled spray on, spray off and/or spray direction controlled by the control system.

25. The aerial robotic sensor and manipulation system according to claim 15, further including:
a mechanical self-cleaning mechanism configured to wipe clean or wipe-off the tip positioning mechanism while it drives upwards towards the robotic base.

26. The aerial robotic sensor and manipulation system according to claim 15, further comprising:
a force detection sensor or a visual sensor in communication with the control system and directly or indirectly detecting forces applied on the tip positioning mechanism or the robotic sensor and manipulation platform for detecting encountered obstacles or entanglements of the sensing and manipulation tip.

27. The aerial robotic sensor and manipulation platform according to claim 15, further comprising:
a force detection or visual sensor in communication with the control system and directly or indirectly detecting forces applied on the tip positioning mechanism or the platform for detecting encountered obstacles or entanglements of the sensing and manipulation tip.

28. The aerial robotic sensor and manipulation platform according to claim 15, further comprising
a force detection means in communication with the control system, detecting tension forces applied to at least one of the aerial platform positioning cables.

29. The aerial robotic sensor and manipulation platform according to claim 15, further including:
a mechanical self-cleaning mechanism configured to wipe clean or wipe-off the sensing and manipulation tip, the mechanical self-cleaning mechanism located at a separate cleaning station accessible by the robotic sensor and manipulation platform within a work envelope of the robotic sensor and manipulation platform.

30. The aerial robotic sensor and manipulation platform according to claim 15, wherein
the at least one distance sensor includes a LiDAR sensor detecting distance to nearby plants and objects.

31. A method for configuring a robotic sensor and manipulation platform to connect directly or indirectly to an aerial support and positioning system, the robotic sensor and manipulation platform manufactured using the step of:
connecting a robotic base to the robotic sensor and manipulation platform
moving the robotic base to command positions using the aerial support and positioning system;
deploying at least one sensing and manipulation tip from the robotic base, comprising the steps:
selecting one or more sensors from a set:
taking images using at least one camera;
detecting distance to nearby plants and objects using:
at least one distance sensor;
at least one temperature sensor;
at least one air quality sensor;
at least one airflow sensor,
at least one light intensity and/or light spectrum sensor;
at least one tip orientation detection means, detecting rotation orientation of the sensing and manipulation tip relative to the robotic base; and
at least one humidity sensor;
at least one CO₂ sensor; and
at least one fluorescence sensor, fluorescence filter or filter cube;
using positioning commands from a control system for configuring a tip positioning mechanism having a motor drive, arranging the tip positioning mechanism on the robotic base and connecting the sensing and manipulation tip to the robotic base, where the tip positioning mechanism is operable to move the sensing and manipulation tip to commanded positions above or in the plant canopy.

32. A method for configuring a robotic sensor and manipulation platform so to recognize critical areas within the plant canopy comprising the steps of:
determining locations in the plant canopy for measuring the presence of a microclimate;
coarsely sampling the plant canopy at each of the locations to determine atmospheric conditions;
collecting atmospheric data from each location and identifying critical areas;
subsampling each of the critical areas to determine the critical areas requiring additional efforts;
computing a heat map of the plant canopy showing the critical areas; and
scheduling additional visits to the critical areas by the robotic sensor and manipulation platform for application of water, fertilizers, and/or pesticides.

33. A method for configuring a robotic sensor and manipulation platform for detecting bugs, pests and insects comprising the steps of:
computing a plurality of locations to visit within a plant canopy;
determining each one of the locations is above or within the plant canopy;
moving the robotic sensor and manipulation platform to each location;
utilizing at least one senor to determine if obstacles are present when the location is above the plant canopy;
using a camera to take an image of the location;
determining if bugs, pest and insects are present from the image; and
reporting the presence of the bugs, pests or insects so the application of a pesticide can be scheduled in a future visit

34. A method of operating a robotic sensor and manipulation platform for trimming plants or obtaining plant measurements, comprising the steps of:
determining targeted plant locations within the plant canopy plants where plants are to be sampled or trimmed;
moving the at least one sensing and manipulation tip to a resting platform;
attaching one of more manipulation attachments from the resting platform onto the at least one sensing and manipulation tip, the one or more manipulation attachments selected from the set:
a cutting device operable by the control system to trim, prune or cut plant material from plants in a geometric plant growth area;
a handling device operable by the control system to hold, grasp or stabilize certain areas of a plant while deriving further measurements;
a spray device operable by the control system and having one or more directional spray nozzles;
a needle device operable by the control system to derive plant measurements beneath an outer plant surface, wherein the needle device includes a plant sap measuring device; and/or
an extensible arm operable by the control system, the extensible arm having either folding arm sections or a telescoping arm sections, wherein one or more manipulation attachments are selectively and detachably connected to the extensible arm under control of the control system;
wherein for each plant to be sampled or trimmed the method further includes:
computing a path plan for the moving the at least one sensing and manipulation tip above or within the plant canopy to access a next plant to be sampled or trimmed;
executing the path plan moving the at least one sensing and manipulation tip with the one or more manipulation attachments into position to access the next plant to be sampled or trimmed; and
performing plant trimming or obtaining plant sample measurements of the next plant to be sampled or trimmed.
